(19) United States
(12) Patent Application Publication
(10) Pub. No.: US 2024/0298478 A1
(43) Pub. Date: Sep. 5, 2024

(54) DISPLAY DEVICE AND METHOD OF MANUFACTURING THE SAME

(71) Applicant: Samsung Display Co., Ltd., Yongin-si (KR)

(72) Inventor: SANG MIN YI, Yongin-si (KR)

(73) Assignee: Samsung Display Co., Ltd., Yongin-si (KR)

(21) Appl. No.: 18/527,825

(22) Filed: Dec. 4, 2023

(30) Foreign Application Priority Data
Mar. 2, 2023 (KR) 10-2023-0027627

(51) Int. Cl. H10K 59/122; H10K 59/12

(52) U.S. Cl. CPC H10K 59/122; H10K 59/1201

(57) ABSTRACT

A display device includes a circuit layer disposed on a base layer, a pixel definition layer disposed on the circuit layer and provided with first, second, and third light emitting openings, and first, second, and third light emitting elements disposed on the circuit layer and including light emitting patterns disposed in the first, second, and third light emitting openings. The pixel definition layer has a first gap corresponding to a distance between the first and third light emitting openings and a second gap corresponding to a distance between the first and second light emitting openings. A difference between the first gap and the second gap is determined according to a difference in size of a shadow area of at least one of the light emitting patterns and a difference in deviation of a pixel position accuracy (PPA) of the at least one of light emitting patterns.

### CROSS-REFERENCE TO RELATED APPLICATION

This application claims priority to and benefits of Korean Patent Application No. 10-2023-0027627 under 35 U.S.C. § 119, filed in the Korean Intellectual Property Office on Mar. 2, 2023, the entire contents of which are incorporated herein by reference.

### BACKGROUND

### 1. Technical Field

The disclosure relates to a display device and a method of manufacturing the display device with improved reliability.

### 2. Description of the Related Art

Display devices, such as televisions, mobile phones, tablet computers, navigation devices, and game devices, include a display panel displaying an image. The display panel includes pixels, and each of the pixels includes a driving element such as a transistor and a display element such as an organic light emitting diode. The display element is formed by depositing an electrode, a functional layer, and a light emitting pattern on a substrate using a mask. The light emitting pattern is formed in different positions depending on deposition process conditions, specifications and alignments of the mask, etc., and a deposition accuracy of the light emitting patterns has been increasing.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provides a display device with improved reliability.

Embodiments also provides a method of manufacturing the display device.

However, embodiments of the disclosure are not limited to those set forth herein. The above and other embodiments will become more apparent to one of ordinary skill in the art to which the disclosure pertains by referencing the detailed description of the disclosure given below.

Embodiments of the disclosure provide a display device including a circuit layer disposed on a base layer, a pixel definition layer disposed on the circuit layer and provided with a first light emitting opening, a second light emitting opening, and a third light emitting opening, a first light emitting element disposed on the circuit layer and comprising a light emitting pattern disposed in the first light emitting opening, a second light emitting element disposed on the circuit layer and comprising a light emitting pattern disposed in the second light emitting opening, and a third light emitting element disposed on the circuit layer and including a light emitting pattern disposed in the third light emitting opening. The pixel definition layer includes a first gap corresponding to a distance between the first light emitting opening and the third light emitting opening and a second gap corresponding to a distance between the first light emitting opening and the second light emitting opening. A difference between the first gap and the second gap is determined according to a difference in size of a shadow area of at least one of the light emitting patterns and a difference in a deviation of a pixel position accuracy (PPA) of the at least one of the light emitting patterns.

The first, second, and third light emitting elements may emit first, second, and third color lights different from each other.

The third color light may have a wavelength range smaller than a wavelength range of the first color light and a wavelength range of the second color light.

The first color light, the second color light, and the third color light may be respectively red, green, and blue color lights.

The first light emitting opening and the second light emitting opening may be spaced apart from the third light emitting opening in a first direction, and the first light emitting opening may be spaced apart from the second light emitting opening in a second direction intersecting the first direction.

The third light emitting opening may overlap the first light emitting opening and the second light emitting opening in the first direction.

A length in the second direction of the third light emitting opening may be greater than a length in the second direction of the first light emitting opening.

The shadow area may correspond to a part of areas in which the at least one of the light emitting patterns, and the at least one of the light emitting patterns in the shadow area may have a thickness smaller than a thickness of the at least one of the light emitting patterns at a center of at least one of the first, second, and third light emitting openings corresponding to the at least one of the light emitting patterns.

The deviation of the PPA may correspond to a difference in position between the center of the at least one of the first, second, and third light emitting openings corresponding to the at least one of the light emitting patterns and a center of the at least one of the light emitting patterns.

The first gap (G1) and the second gap (G2) may satisfy the following Equation 1 of |G1−G2|=|2 [(SA1−SA2)+(PPA1−PPA2)]|, wherein SA1 denotes a size in the first direction of the shadow area, SA2 denotes a size in the second direction of the shadow area, PPA1 denotes a difference in position between a center of the at least one of the first, second, and third light emitting openings and a center of the at least one of the light emitting patterns in the first direction, and PPA2 denotes a difference in position between a center of the at least one of the first, second, and third light emitting openings and a center of the at least one of the light emitting patterns in the second direction.

The first gap may be greater than the second gap in case that a sum of a difference between the SA1 and the SA2 and a difference between the PPA1 and the PPA2 is a positive number.

The first gap may be smaller than the second gap in case that a sum of a difference between the SA1 and the SA2 and a difference between the PPA1 and the PPA2 is a negative number.

Embodiments of the disclosure provide a display device including a circuit layer disposed on a base layer, a pixel definition layer disposed on the circuit layer and provided with a first light emitting opening, a second light emitting opening, and a third light emitting opening, a first light emitting element disposed in the first light emitting opening and comprising a light emitting pattern, a second light emitting element disposed in the second light emitting opening and comprising a light emitting pattern, and a third light emitting element disposed in the third light emitting opening and including a light emitting pattern. The first light emitting opening and the third light emitting opening are spaced apart from each other with a first gap in a first direction. The first light emitting opening and the second light emitting opening are spaced apart from each other with a second gap in a second direction intersecting the first direction. A difference between the first gap and the second gap is determined according to a difference in size of a shadow area of at least one of the light emitting patterns and a difference in a deviation of a pixel position accuracy (PPA) of the at least one of the light emitting patterns.

Embodiments of the disclosure provide a method of manufacturing a display device. The method of manufacturing the display device includes providing a process substrate including first electrodes, forming a pixel definition layer which is provided with a first light emitting opening, a second light emitting opening, and a third light emitting opening to respectively expose portions of the first electrodes, on the process substrate, forming a light emitting pattern overlapping each of the first, second, and third light emitting openings in a plan view, and forming a second electrode on the light emitting pattern. The forming of the pixel definition layer includes determining a first gap corresponding to a distance between the first light emitting opening and the third light emitting opening, and determining a second gap corresponding to a distance between the first light emitting opening and the second light emitting opening. A difference between the first gap and the second gap is determined according to a difference in size of a shadow area of at least one of the light emitting patterns and a difference in a deviation of a pixel position accuracy (PPA) of the at least one of the light emitting patterns.

The first light emitting opening and the second light emitting opening may be spaced apart from the third light emitting opening in a first direction, and the first light emitting opening may be spaced apart from the second light emitting opening in a second direction intersecting the first direction.

The shadow area may correspond to a part of the at least one of the light emitting patterns, and the part of the at least one of the light emitting patterns in the shadow area may have a thickness smaller than a thickness of a part of the at least one of the light emitting patterns at a center of at least one of the first, second, and third light emitting openings corresponding to the at least one of the light emitting patterns.

The deviation of the PPA deviation may correspond to a difference in position between a center of a designed light emitting pattern and a center of a deposited light emitting pattern.

The first gap (G1) and the second gap (G2) may satisfy the following Equation 1 of |G1−G2|=|2 [(SA1−SA2)+(PPA1−PPA2)]|, wherein SA1 denotes a size in the first direction of the shadow area, SA2 denotes a size in the second direction of the shadow area, PPA1 denotes a difference in position between a center of the at least one of the first, second, and third light emitting openings and a center of the at least one of the light emitting patterns in the first direction, and PPA2 denotes a difference in position between a center of the at least one of the first, second, and third light emitting openings and a center of the at least one of the light emitting patterns in the second direction.

The first gap may be greater than the second gap in case that a sum of a difference between the SA1 and the SA2 and a difference between the PPA1 and the PPA2 is a positive number.

The first gap may be smaller than the second gap in case that a sum of a difference between the SA1 and the SA2 and a difference between the PPA1 and the PPA2 may be a negative number.

According to the above, the gaps of the pixel definition layer positioned between the light emitting areas may be corrected (or compensated) in the display device. The gaps of the pixel definition layer may be corrected (or compensated) by taking into account the size of the shadow area and the pixel position accuracy. Accordingly, defects in deposition caused by the deposition process conditions and the shadow area may be reduced, and reliability of the display device may be improved.

### BRIEF DESCRIPTION OF THE DRAWINGS

An additional appreciation according to the embodiments of the disclosure will become more apparent by describing in detail the elements thereof with reference to the accompanying drawings, wherein:

FIG. 1 is a schematic perspective view of a display device according to an embodiment of the disclosure;

FIG. 2 is a schematic exploded perspective view of a display device according to an embodiment of the disclosure;

FIG. 3 is a schematic cross-sectional view of a display module according to an embodiment of the disclosure;

FIG. 4 is a schematic plan view of a display panel according to an embodiment of the disclosure;

FIG. 5 is a schematic plan view of a display panel according to an embodiment of the disclosure;

FIG. 6 is a schematic cross-sectional view of the display panel taken along line I-I′ of FIG. 5;

FIG. 7A is a schematic cross-sectional view of a process of manufacturing a display panel according to an embodiment of the disclosure;

FIG. 7B is a schematic enlarged cross-sectional view of an area bb of FIG. 7A; and

FIG. 8 is a schematic plan view of a process of manufacturing a display panel according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

When an element (or area, layer, or portion) is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, a display device and a method of manufacturing the display device according to embodiments of the disclosure are described with reference to accompanying drawings.

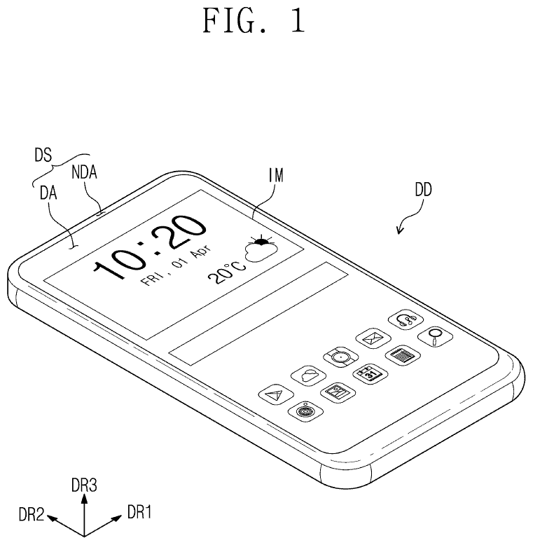

FIG. 1 is a schematic perspective view of a display device DD according to an embodiment of the disclosure.

Referring to FIG. 1, the display device DD may be activated (or operated) in response to electrical signals and may display an image IM. For example, the display device DD may be applied to a large-sized display device, such as a television set, an outdoor billboard, etc., and a small and medium-sized display device, such as a monitor, a mobile phone, a tablet computer, a navigation part, a game part, etc. However, the disclosure is not limited thereto, and the display device DD may be applied to other display devices without departing from the disclosure. In the embodiment, the display device DD may be applied to a mobile phone.

The display device DD may be rigid or flexible. The term “flexible” used herein refers to the property of being able to be bent from a structure that is completely bent to a structure that is bent at the scale of a few nanometers. For example, the display device DD that is flexible may be a curved display device, a rollable display device, or a foldable display device.

The display device DD may have a rectangular shape with short sides extending in a first direction DR1 and long sides extending in a second direction DR2 intersecting (e.g., crossing) the first direction DR1. However, the shape of the display device DD is not limited to the rectangular shape, and the display device DD may have various shapes, such as a circular shape, a polygonal shape, etc.

In the embodiment, a third direction DR3 may be substantially perpendicular to a plane defined by the first direction DR1 and the second direction DR2. Front (or upper) and rear (or lower) surfaces of each member of the display device DD may be opposite to each other in the third direction DR3, and a normal line direction of each of the front and rear surfaces may be substantially parallel to the third direction DR3. A distance (e.g., separation distance) between the front and rear surfaces of each member in the third direction DR3 may correspond to a thickness of the member in the third direction DR3.

In the disclosure, the expression “in a plan view” may mean a state of being viewed in the third direction DR3. In the disclosure, the expression “on a cross-section” may mean a state of being viewed in the first direction DR1 or the second direction DR2. Directions indicated by the first, second, and third directions DR1, DR2, and DR3 are relative to each other, and thus, the directions indicated by the first, second, and third directions DR1, DR2, and DR3 may be changed to other directions.

The display device DD may display the image IM through a display surface DS. The display surface DS may correspond to a front surface of the display device DD. The display surface DS of the display device DD may be substantially parallel to the plane defined by the first direction DR1 and the second direction DR2 and may display the image IM in the third direction DR3 intersecting the plane. However, the shape of the display surface DS is not limited thereto, and the display surface DS may further include a curved surface bent from a side of the plane.

The display surface DS of the display device DD may include a display part DA and a non-display part NDA. The display part DA may be a part through which the image IM is displayed, and the image IM may be displayed within the display surface DS of the display device DD. The image IM may be displayed through the display part DA in the third direction DR3. The image IM may include a still image, a video, or the like. FIG. 1 schematically shows a clock widget and application icons as an example of the image IM.

The non-display part NDA may be disposed adjacent to the display part DA. The image IM may not be displayed through the non-display part NDA within the display surface DS. The non-display part NDA may have a transmittance lower than that of the display part DA. The non-display part NDA may surround the display part DA, however, the disclosure is not limited thereto. The non-display part NDA may be defined adjacent to a side (e.g., only one side) of the display part DA or may be omitted.

According to an embodiment, the display device DD may sense an external input applied thereto from the outside. The external input may include various external inputs provided from the outside, such as force, pressure, temperature, light, etc. The external input may include a proximity input (e.g., a hovering input) applied in case that an object approaches close to or adjacent to the display device DD at a distance (e.g., a predetermined or selectable distance) and a touch input, e.g., a touch by a hand of a user or a pen.

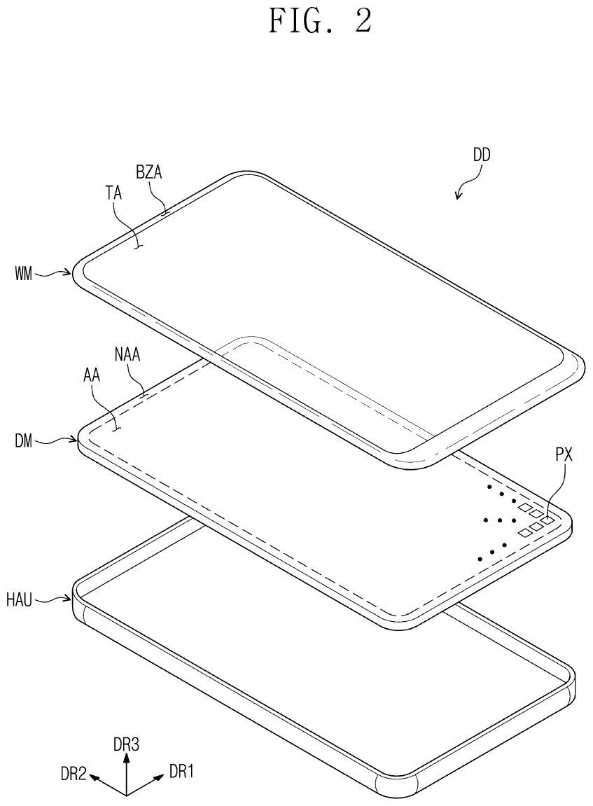

FIG. 2 is a schematic exploded perspective view of the display device DD according to an embodiment of the disclosure.

Referring to FIG. 2, the display device DD may include a window WM, a display module DM, and a housing HAU, however, components of the display device DD are not limited thereto. According to an embodiment, the display device DD may further include a functional layer, such as an anti-reflective layer, disposed between the display module DM and the window WM or an electronic module, such as a camera module, a battery module, or the like, disposed between the display module DM and the housing HAU.

The window WM may be disposed on the display module DM. The window WM may cover a front surface of the display module DM and may protect the display module DM from external impacts and scratches. The window WM may be coupled with the display module DM by an adhesive layer.

The window WM may include an optically transparent insulating material. For example, the window WM may include a glass film or a synthetic resin film as a base film. The window WM may further include functional layers, such as an anti-fingerprint layer, a phase control layer, a hard coating layer, etc., disposed on the base film.

The front surface of the window WM may correspond to the front surface of the display device DD. The front surface of the window WM may include a transmission area TA and a bezel area BZA.

The transmission area TA may be an optically transparent area. The transmission area TA may transmit the image provided from the display module DM, and the user may view the image through the transmission area TA. In the embodiment, the transmission area TA may have a quadrangular shape, however, the disclosure is not limited thereto, and the transmission area TA may have various shapes.

The bezel area BZA may be defined adjacent to the transmission area TA. The transmission area TA may have a shape defined by the bezel area BZA. For example, the bezel area BZA may be disposed outside the transmission area TA and may surround the transmission area TA. However, the disclosure is not limited thereto, and the bezel area BZA may be disposed adjacent to a side (e.g., only one side) of the transmission area TA. In the embodiment, the bezel area BZA may be disposed on the front surface of the display device DD. However, the disclosure is not limited thereto, and the bezel area BZA may be disposed on a side surface of the display device DD.

The bezel area BZA may have a light transmittance lower than that of the transmission area TA. The bezel area BZA may correspond to an area in which a material having a color (e.g., a predetermined or selectable color) is printed. For example, the bezel area BZA may be printed by the color. The bezel area BZA may block the transmission of the light and may prevent components of the display module DM, which overlap the bezel area BZA in a plan view, from being viewed from the outside.

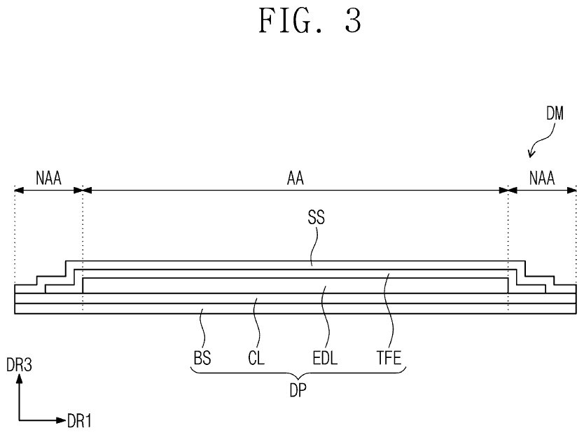

The display module DM may be disposed between the window WM and the housing HAU. The display module DM may include a display area AA and a non-display area NAA. The display area AA may correspond to the display area AA of the display panel DP (e.g., refer to FIG. 3) and the non-display area NAA may correspond to the non-display area NAA of a display panel DP. Detailed descriptions of the display area AA and the non-display area NAA are provided below. Pixels PX may be arranged in the display area AA and each of the pixels PX may generate a light in response to electrical signals. For example, each of the pixels PX may include a light emitting element and may display the image IM (e.g., refer to FIG. 1) using the light generated from the light emitting element. The display area AA may overlap at least part of the transmission area TA in a plan view.

The non-display area NAA may be defined adjacent to the display area AA. For example, the non-display area NAA may surround the display area AA, however, the disclosure is not limited thereto. According to an embodiment, the non-display area NAA may be defined in various shapes. A driving circuit, a signal line, and a pad may be disposed in the non-display area NAA and drive the light emitting element in the display area AA. The non-display area NAA may overlap at least part of the bezel area BZA in a plan view, and components disposed in the non-display area NAA may be prevented from being viewed from the outside by the bezel area BZA.

The window WM may be coupled with the housing HAU and form an external appearance of the display device DD. The display module DM may be accommodated in an inner space formed by the window WM and the housing HAU coupled with the window WM.

The housing HAU may include a material with a relatively high rigidity. For example, the housing HAU may include a glass, plastic, or metal material. The housing HAU may include frames and/or plates including combinations thereof. The housing HAU may absorb external impacts applied thereto from the outside and protect the display module DM. The housing HAU may prevent a foreign substance or moisture from entering the display module DM.

FIG. 3 is a schematic cross-sectional view of the display module DM according to an embodiment of the disclosure.

Referring to FIG. 3, the display module DM may include the display panel DP and an input sensor layer SS.

The display panel DP may display the image IM (e.g., refer to FIG. 1) in response to electrical signals. The display panel DP according to an embodiment may be a light emitting type display panel, however, the disclosure is not limited thereto. For instance, the display panel DP may be an organic light emitting display panel, an inorganic light emitting display panel, a quantum dot light emitting display panel, or the like. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and/or a quantum rod. Hereinafter, the organic light emitting display panel is described as an example of the display panel DP.

The display panel DP may include a base layer BS, a circuit layer CL, a display element layer EDL, and an encapsulation layer TFE. The display panel DP may include the display area AA (e.g., refer to FIG. 2) displaying the image IM and the non-display area NAA (e.g., refer to FIG. 2) adjacent to the display area AA.

The base layer BS may provide a base surface on which the circuit layer CL is disposed. The base layer BS may be a rigid substrate or a flexible substrate that is bendable, foldable, or rollable. The base layer BS may include a glass substrate, a metal substrate, or a polymer substrate, however, the disclosure is not limited thereto. According to an embodiment, the base layer BS may include an inorganic layer, a synthetic resin layer, or a composite layer.

The base layer BS may have a multi-layer structure. For example, the base layer BS may include synthetic resin layers and an inorganic layer provided in a single layer or multi-layers and disposed between the synthetic resin layers. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. However, the material for the synthetic resin layer is not limited thereto.

The circuit layer CL may be disposed on the base layer BS. The circuit layer CL may include at least one insulating layer, a semiconductor pattern, and a conductive pattern. The insulating layer, a semiconductor layer, and a conductive layer may be formed by a coating or depositing process. The insulating layer, the semiconductor layer, and the conductive layer may be patterned through several photolithography processes, and thus, the insulating layer, the semiconductor pattern, and the conductive pattern of the circuit layer CL may be formed. The insulating layer, the semiconductor pattern, and the conductive pattern may form driving circuits such as transistors, signal lines, and pads, which are included in the circuit layer CL.

The display element layer EDL may be disposed on the circuit layer CL. The display element layer EDL may include light emitting elements disposed in the display area AA. The light emitting elements of the display element layer EDL may be electrically connected to the driving elements of the circuit layer CL and may emit a light through the display area AA in response to a signal from the driving element.

The encapsulation layer TFE may be disposed on the display element layer EDL and may encapsulate the light emitting elements. The encapsulation layer TFE may include at least one thin layer. The encapsulation layer TFE may improve an optical efficiency of the display element layer EDL or may protect the display element layer EDL. The encapsulation layer TFE may include at least one of an inorganic layer and an organic layer.

The input sensor layer SS may be disposed on the display panel DP. The input sensor layer SS may be formed on the display panel DP through successive processes. The input sensor layer SS may be disposed on (e.g., be directly disposed on) the display panel DP without a separate adhesive layer, however, the disclosure is not limited thereto. According to an embodiment, the input sensor layer SS may be coupled with the display panel DP by an adhesive layer.

The input sensor layer SS may include at least one of an input sensor, an antenna sensor, and a fingerprint sensor. For example, the input sensor layer SS may include the input sensor. The input sensor may sense the external input and may provide an input signal including information about the external input. Thus, the display panel DP may display an image correspond to the external input. The input sensor may be driven in various methods, such as a capacitive method, a resistive film method, an infrared ray method, a sonic method, or a pressure method, however, the disclosure is not limited thereto.

The structure of the display module DM is not limited to FIG. 3, and the display module DM may further include a protective member disposed under the display panel DP or an anti-reflective layer disposed on the display panel DP.

The protective member may be disposed on a rear surface of the display panel DP and may protect the display panel DP from external impacts. The protective member may include a cushion layer that absorbs the impacts, a heat dissipation layer that prevents heat from being transferred to the display panel DP, or a shielding layer that blocks a light reflection or an electromagnetic wave.

The anti-reflective layer may be disposed on the input sensor layer SS. The anti-reflective layer may be disposed on the input sensor layer SS through successive processes without an adhesive layer or may be coupled with the input sensor layer SS with an adhesive layer. The anti-reflective layer may be disposed between the display panel DP and the input sensor layer SS.

The anti-reflective layer may include various embodiments and reduce a reflectance with respect to an external light incident thereto from the outside of the display device DD (e.g., refer to FIG. 1). For example, the anti-reflective layer may include a polarizing film including a retarder and/or a polarizer, reflective layers destructively interfering with reflected lights, or color filters disposed to correspond to an arrangement and a light emission color of the pixels (e.g., refer to FIG. 2).

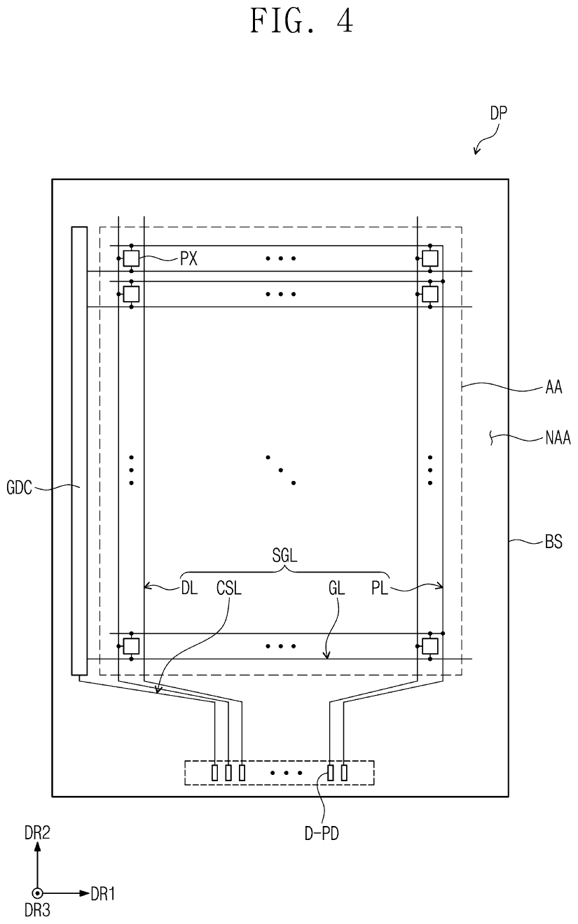

FIG. 4 is a schematic plan view of the display panel DP according to an embodiment of the disclosure.

Referring to FIG. 4, the display panel DP may include the base layer BS, the pixels PX, signal lines SGL electrically connected to the pixels PX, a driving circuit GDC, and pads D-PD.

The base layer BS may provide the base surface on which elements and lines of the display panel DP are disposed in the plane parallel to the first direction DR1 and the second direction DR2. The front surface of the base layer BS may be divided into the display area AA and the non-display area NAA of the display panel DP described above.

The pixels PX may be disposed in the display area AA. Each of the pixels PX may include a pixel driving circuit and a light emitting element electrically connected to the pixel driving circuit. The pixel driving circuit may include transistors, e.g., a switching transistor, a driving transistor, etc., and at least one capacitor. The pixels PX may emit the light in response to the electrical signals applied thereto and display the image IM (e.g., refer to FIG. 1) in the display area AA.

The driving circuit GDC, at least some of the signal lines SGL, and the pads D-PD, which drive the pixels PX, may be disposed in the non-display area NAA. The signal lines SGL may include gate lines GL, data lines DL, a power line PL, and a control signal line CSL. Each of the gate lines GL and each of the data lines DL may be electrically connected to a corresponding pixel among the pixels PX. The gate lines GL may extend in a direction parallel to the first direction DR1 and may be electrically connected to the driving circuit GDC. The data lines DL may extend in a direction parallel to the second direction DR2 and may be electrically insulated from the gate lines GL while intersecting the gate lines GL in a plan view. The power line PL may be electrically connected to the pixels PX. The control signal line CSL may be electrically connected to the driving circuit GDC and may provide control signals to the driving circuit GDC.

The driving circuit GDC may include a gate driving circuit. The gate driving circuit may generate gate signals and may sequentially output the generated gate signals to the gate lines GL. The gate driving circuit may further output another control signal to the pixel driving circuit.

The pads D-PD may be disposed adjacent to a lower end of the non-display area NAA. The pads D-PD may be spaced apart from each other in the first direction DR1. The pads D-PD may be electrically connected to a flexible circuit board provided on the display panel DP. Each of the pads D-PD may be electrically connected to a corresponding signal line among the signal lines SGL and may be electrically connected to the pixels PX via the signal lines SGL.

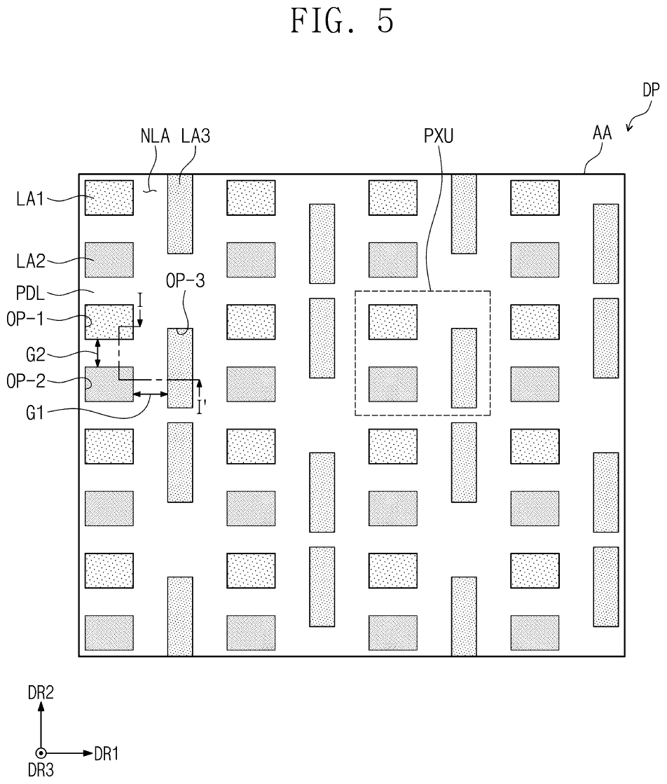

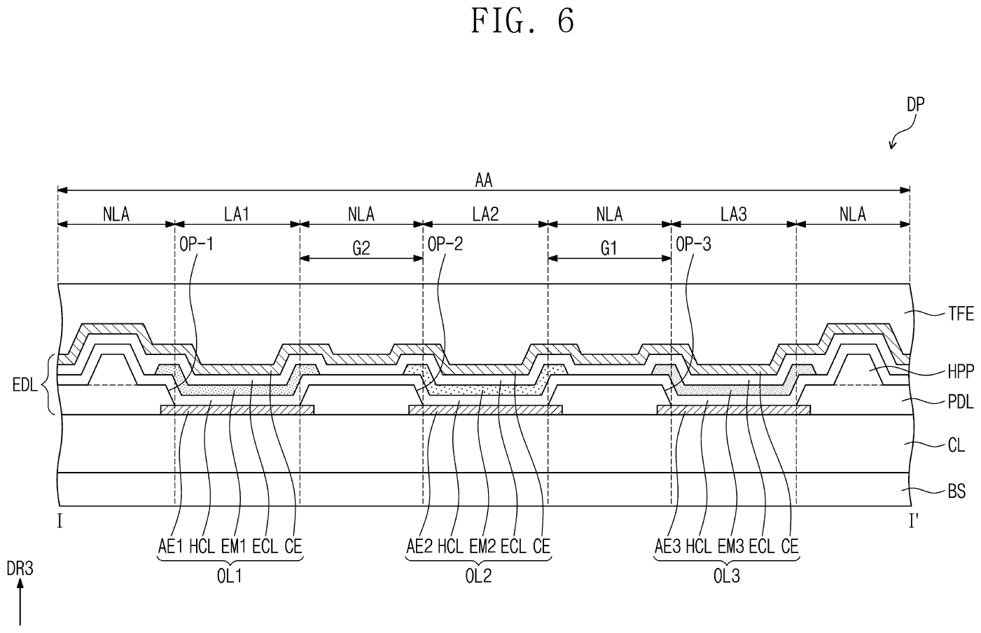

FIG. 5 is a schematic plan view of the display panel DP according to an embodiment of the disclosure. FIG. 5 is an enlarged view of a portion of the display area AA of the display panel DP. FIG. 6 is a schematic cross-sectional view of the display panel DP taken along line I-I′ of FIG. 5 according to an embodiment of the disclosure.

Referring to FIGS. 5 and 6, the display panel DP may include the display area AA displaying the image IM (e.g., refer to FIG. 1). In the embodiment, the display area AA may be substantially parallel to the plane defined by the first direction DR1 and the second direction DR2. The display area AA of the display panel DP may include light emitting areas LA1, LA2, and LA3 and a non-light-emitting area NLA.

The display panel DP may include the base layer BS, the circuit layer CL, the display element layer EDL, and the encapsulation layer TFE, and detailed descriptions thereof are the same as those described earlier. The display element layer EDL may include light emitting elements OL1, OL2, and OL3 and a pixel definition layer PDL.

The light emitting elements OL1, OL2, and OL3 and the pixel definition layer PDL may be disposed on the circuit layer CL. Each of the light emitting elements OL1, OL2, and OL3 may be at least one of an organic light emitting element, an inorganic light emitting element, a quantum dot light emitting element, a micro-LED light emitting element, a nano-LED light emitting element, a quantum dot light emitting element, an electrophoretic element, and an electrowetting element. However, the light emitting elements OL1, OL2, and OL3 are not limited thereto. In case that the light is generated in response to electrical signals or an amount of the light is controlled by the electrical signals, the light emitting elements OL1, OL2, and OL3 may have various elements.

The light emitting elements OL1, OL2, and OL3 may include a first light emitting element OL1, a second light emitting element OL2, and a third light emitting element OL3. Each of the first, second, and third light emitting elements OL1, OL2, and OL3 may include a corresponding first electrode among first electrodes AE1, AE2, and AE3, a hole control layer HCL, a corresponding light emitting pattern among light emitting patterns EM1, EM2, and EM3, an electron control layer ECL, and a second electrode CE, which are sequentially stacked.

The light emitting areas LA1, LA2, and LA3 may correspond to areas in which the light emitting elements OL1, OL2, and OL3 of the display panel DP are respectively disposed. The light emitting areas LA1, LA2, and LA3 may include a first light emitting area LA1, a second light emitting area LA2, and a third light emitting area LA3. The first, second, and third light emitting elements OL1, OL2, and OL3 may be disposed in the first, second, and third light emitting areas LA1, LA2, and LA3, respectively. The first electrodes AE1, AE2, and AE3 of the first, second, and third light emitting elements OL1, OL2, and OL3 may respectively correspond to the first, second, and third light emitting areas LA1, LA2, and LA3 and may be spaced apart from each other on the circuit layer CL.

A first light emitting opening OP-1, a second light emitting opening OP-2, and a third light emitting opening OP-3 may be defined through the pixel definition layer PDL and respectively correspond to the first electrodes AE1, AE2, and AE3. The first, second, and third light emitting openings OP-1, OP-2, and OP-3 may respectively overlap the first electrodes AE1, AE2, and AE3 in a plan view, and each of the first, second, and third light emitting openings OP-1, OP-2, and OP-3 may expose at least part of a corresponding first electrode among the first electrodes AE1, AE2, and AE3.

The pixel definition layer PDL may surround the first electrodes AE1, AE2, and AE3 in a plan view and may define the first, second, and third light emitting areas LA1, LA2, and LA3 from which the lights are emitted. For example, the first electrode AE1 of the first light emitting element OL1 exposed through the first light emitting opening OP-1 may correspond to the first light emitting area LA1. The first electrode AE2 of the second light emitting element OL2 exposed through the second light emitting opening OP-2 may correspond to the second light emitting area LA2. The first electrode AE3 of the third light emitting opening OP-3 exposed through the third light emitting element OL3 may correspond to the third light emitting area LA3.

The light emitting areas LA1, LA2, and LA3 may respectively correspond to areas from which lights provided by the first, second, and third light emitting elements OL1, OL2, and OL3 exit. For example, the first, second, and third light emitting areas LA1, LA2, and LA3 may correspond to the first, second, and third light emitting elements OL1, OL2, and OL3, respectively. The first, second, and third light emitting areas LA1, LA2, and LA3 may be distinguished from each other depending on colors of lights traveling to the outside of the display panel DP. For example, each of the first light emitting area LA1, the second light emitting area LA2, and the third light emitting area LA3 may emit one of a red light, a green light, and a blue light. However, the colors of the lights emitted from the first, second, and third light emitting areas LA1, LA2, and LA3 are not limited thereto. The blue light has a wavelength range smaller than a wavelength range of the green light. The green light has a wavelength range smaller than a wavelength range of the red light.

An area in which the pixel definition layer PDL is disposed may correspond to the non-light-emitting area NLA. The non-light-emitting area NLA may define a boundary between the first, second, and third light emitting areas LA1, LA2, and LA3 and may surround the first, second, and third light emitting areas LA1, LA2, and LA3 in a plan view. The pixel definition layer PDL corresponding to the non-light-emitting area NLA may prevent colors of the lights from being mixed between the first, second, and third light emitting areas LA1, LA2, and LA3.

The first, second, and third light emitting areas LA1, LA2, and LA3 may have an alignment (e.g., a predetermined or selectable arrangement) in a plan view. The first light emitting area LA1 and the second light emitting area LA2 may be arranged in the direction parallel to the second direction DR2, and the third light emitting area LA3 may be spaced apart from the first and second light emitting areas LA1 and LA2 in the first direction DR1. The third light emitting area LA3 may overlap the first and second light emitting areas LA1 and LA2 in the first direction DR1.

The first light emitting area LA1 and the second light emitting area LA2 may be spaced apart from each other in the second direction DR2, and the third light emitting area LA3 may be spaced apart from the first and second light emitting areas LA1 and LA2 in the first direction DR1. Thus, the first, second, and third light emitting areas LA1, LA2, and LA3 may define a pixel part PXU. The first light emitting area LA1, the second light emitting area LA2, and the third light emitting area LA3, which define the pixel part PXU, may respectively correspond to first, second, and third pixels.

Each of the first, second, and third light emitting areas LA1, LA2, and LA3 may be provided in plural and may be repeatedly arranged in the display area AA in an arrangement (e.g., a predetermined or selectable arrangement). For example, the display panel DP may include multiple first light emitting areas LA1, multiple second light emitting areas LA2, and multiple light emitting areas LA3. Referring to FIG. 5, the first light emitting areas LA1 may be alternately arranged with the second light emitting areas LA2 along the direction parallel to the second direction DR2. The third light emitting areas LA3 may be spaced apart from the first light emitting area LA1 and the second light emitting area LA2 in the first direction DR1. The third light emitting areas LA3 may be arranged in the second direction DR2.

The third light emitting areas LA3 may be staggered in the first direction DR1 to allow centers thereof to be shifted from each other. For example, the centers of the third light emitting areas LA3 may be arranged in the second direction DR2 and may be shifted from each other in the first direction DR1. The first light emitting areas LA1 may be arranged in the first direction DR1, and the second light emitting areas LA2 may be arranged in the first direction DR1. The first light emitting areas LA1 adjacent to each other in the first direction DR1 may be arranged with the third light emitting area LA3 disposed therebetween (e.g., interposed therebetween), and the second light emitting areas LA2 adjacent to each other in the first direction DR1 may be arranged with the third light emitting area LA3 disposed therebetween (e.g., interposed therebetween). The arrangements of the first, second, and third light emitting areas LA1, LA2, and LA3 are shown in FIG. 5. However, the disclosure is not limited thereto.

The first, second, and third light emitting areas LA1, LA2, and LA3 may have a shape (e.g., a predetermined or selectable shape) in a plan view. For example, each of the first, second, and third light emitting areas LA1, LA2, and LA3 may have a quadrangular shape as shown in FIG. 5, however, the disclosure is not limited thereto. According to an embodiment, each of the first, second, and third light emitting areas LA1, LA2, and LA3 may have a polygonal shape, a circular shape, an oval shape, or the like.

The first, second, and third light emitting areas LA1, LA2, and LA3 may have substantially a same size as each other in a plan view. Light emitting areas with the same plan size may have a same length in the first direction DR1 and the second direction DR2. In other embodiments, light emitting areas may have different lengths in the first direction DR1 and the second direction DR2 while having a same plan size. According to an embodiment, at least two of the first, second, and third light emitting areas LA1, LA2, and LA3 may have different sizes from each other in a plan view. The sizes of the first, second, and third light emitting areas LA1, LA2, and LA3 in the plane may be determined depending on the colors of the lights emitted therefrom or a light emitting efficiency. The first, second, and third light emitting openings OP-1, OP-2, and OP-3 which corresponded with the first, second, and third light emitting areas may have a length and a size which corresponded with the length and size of the first, second, and third light emitting areas LA1, LA2, and LA3.

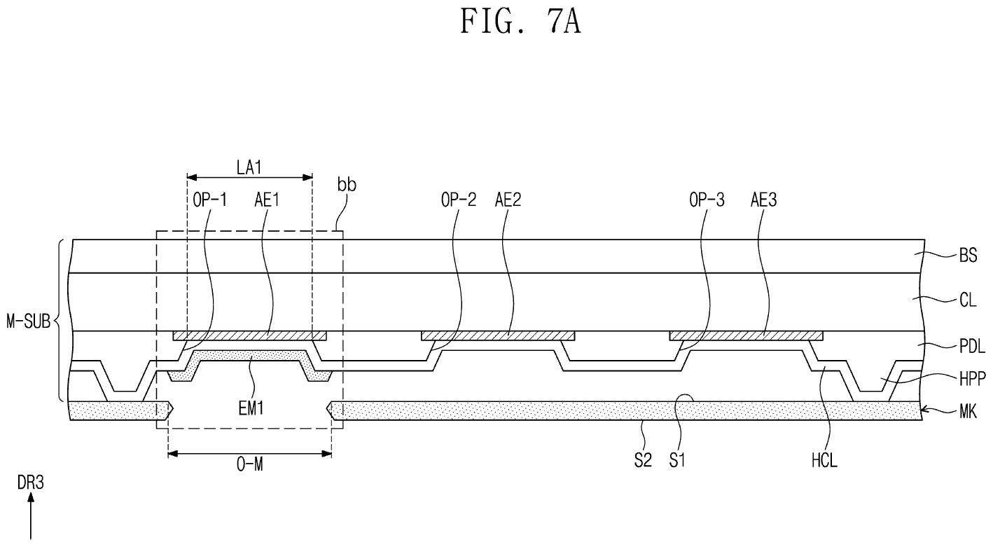

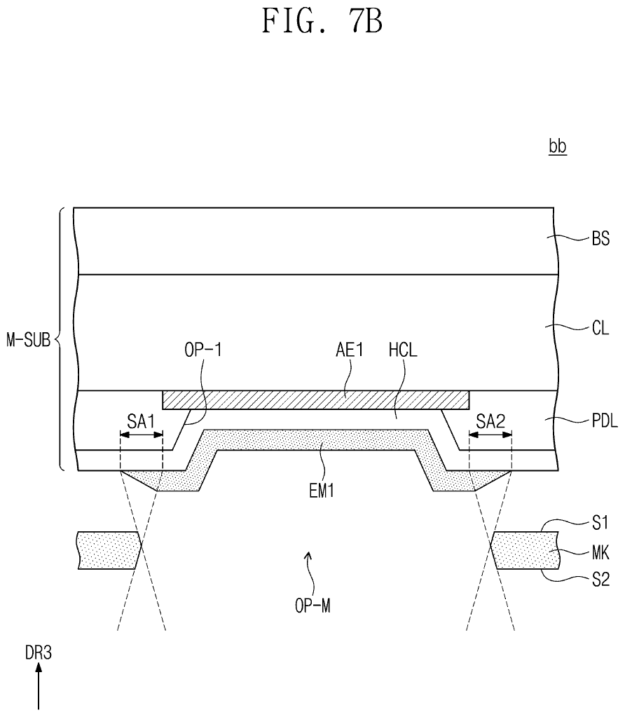

The display element layer EDL may further include a protruding layer HPP disposed on the pixel definition layer PDL. The protruding layer HPP may be disposed on some portions of the non-light-emitting area NLA. The protruding layer HPP may not overlap the first, second, and third light emitting areas LA1, LA2, and LA3 in a plan view. The protruding layer HPP may be disposed on an upper surface of the pixel definition layer PDL. The protruding layer HPP may protrude upward from the upper surface of the pixel definition layer PDL. Accordingly, the protruding layer HPP may support a mask MK (e.g., refer to FIG. 7A) described later in a deposition process and a non-deposition area in an opening O-M (e.g., refer to FIG. 7A) may be spaced apart from the mask MK (e.g., refer to FIG. 7A).

The protruding portion HPP and the pixel definition layer PDL may include a same material and may be integral with each other, however, the disclosure is not limited thereto. According to an embodiment, the protruding portion HPP and the pixel definition layer PDL may include a same material. However, the protruding portion HPP and the pixel definition layer PDL may be formed under different deposition conditions. In other embodiments, the protruding portion HPP may include a material different from that of the pixel definition layer PDL. According to an embodiment, the protruding portion HPP may be omitted.

The light emitting patterns EM1, EM2, and EM3 of the first, second, and third light emitting elements OL1, OL2, and OL3 may be disposed on the first electrodes AE1, AE2, and AE3, respectively. The light emitting patterns EM1, EM2, and EM3 of the first, second, and third light emitting elements OL1, OL2, and OL3 may correspond to the first, second, and third light emitting openings OP-1, OP-2, and OP-3, respectively.

The light emitting patterns EM1, EM2, and EM3 may be formed through the deposition process using the mask MK (e.g., refer to FIG. 7A). For example, the light emitting patterns EM1, EM2, and EM3 may be formed to respectively correspond to the pixels using a mask part (e.g., a fine metal mask (FMM) or the like). The light emitting patterns EM1, EM2, and EM3 may be deposited to have a process margin, and each of the light emitting patterns EM1, EM2, and EM3 may cover an entire area of a corresponding light emitting opening in a plan view. Accordingly, even though the light emitting patterns EM1, EM2, and EM3 are shifted from target points due to a misalignment of the mask MK (e.g., refer to FIG. 7A) in a deposition process, the area defined as the light emitting area may be sufficiently covered.

The light emitting patterns EM1, EM2, and EM3 may include an organic light emitting material, an inorganic light emitting material, a quantum dot, a quantum rod, or the like. The light emitting patterns EM1, EM2, and EM3 of the first, second, and third light emitting elements OL1, OL2, and OL3 may emit lights having different colors from each other. For example, materials respectively included in the light emitting patterns EM1, EM2, and EM3 of the first, second, and third light emitting elements OL1, OL2, and OL3 may be different from each other and may be deposited using different masks MK (e.g., refer to FIG. 7A) from each other, however, the disclosure is not limited thereto.

The hole control layer HCL may be disposed between the first electrodes AE1, AE2, and AE3 and the light emitting patterns EM1, EM2, and EM3. The hole control layer HCL may include at least one of a hole transport layer, a hole injection layer, and an electron blocking layer. The electron control layer ECL may be disposed between the light emitting patterns EM1, EM2, and EM3 and the second electrode CE. The electron control layer ECL may include at least one of an electron transport layer, an electron injection layer, and a hole blocking layer.

The hole control layer HCL and the electron control layer ECL may be commonly disposed in the light emitting areas LA1, LA2, and LA3 and the non-light-emitting area NLA. The hole control layer HCL and the electron control layer ECL, each of which has a layer form, may be commonly deposited in the pixels using an open mask.

The second electrode CE of the first, second, and third light emitting elements OL1, OL2, and OL3 may be provided in an integral shape and may be disposed on the light emitting patterns EM1, EM2, and EM3. For example, the second electrode CE of the first, second, and third light emitting elements OL1, OL2, and OL3 may be a common electrode that serves as a common layer. The second electrode CE may overlap the first, second, and third light emitting areas LA1, LA2, and LA3 and the non-light-emitting area NLA in a plan view.

The encapsulation layer TFE may be disposed on the light emitting elements OL1, OL2, and OL3. The encapsulation layer TFE may include at least one thin layer that encapsulates and protects the light emitting elements OL1, OL2, and OL3 and/or improves the light emitting efficiency of the light emitting elements OL1, OL2, and OL3. For example, the encapsulation layer TFE may include at least one of an inorganic layer protecting the light emitting elements OL1, OL2, and OL3 from moisture and/or oxygen and an organic layer protecting the light emitting elements OL1, OL2, and OL3 from a foreign substance such as dust particles.

The pixel definition layer PDL may have a first gap G1 and a second gap G2. The first gap G1 may correspond to a separation distance in the first direction DR1 between the first light emitting opening OP-1 and the third light emitting opening OP-3 or between the second light emitting opening OP-2 and the third light emitting opening OP-3. The second gap G2 may correspond to a separation distance in the second direction DR2 between the first light emitting opening OP-1 and the second light emitting opening OP-2. The first gap G1 may correspond to a distance between an inner side surface of the pixel definition layer PDL, which defines the first light emitting opening OP-1 (or the second light emitting opening OP-2), and an inner side surface of the pixel definition layer PDL, which defines the third light emitting opening OP-3. The second gap G2 may correspond to a distance between the inner side surface of the pixel definition layer PDL, which defines the first light emitting opening OP-1, and the inner side surface of the pixel definition layer PDL, which defines the second light emitting opening OP-2.

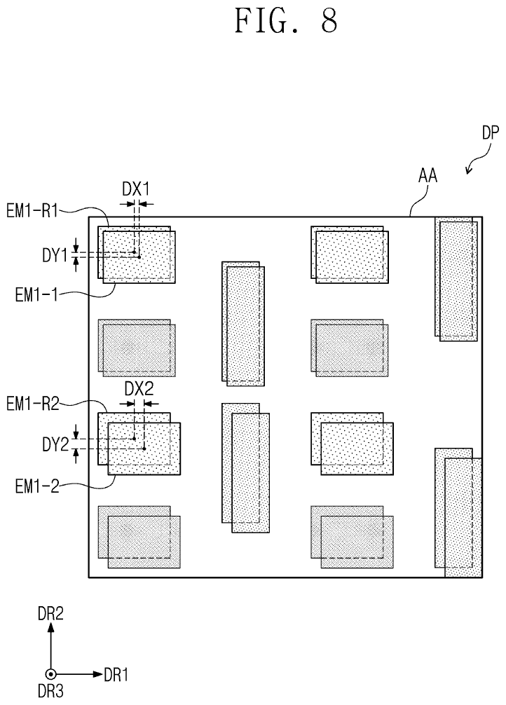

The first gap G1 and the second gap G2 may be determined by taking into account a size of a shadow area in the first direction DR1 and the second direction DR2 and a deposition accuracy. Detailed descriptions of the shadow area and the deposition accuracy are provided below. For example, a difference between the first gap G1 and the second gap G2 may be proportional to a difference in size of the shadow area and a difference in deviation of deposition position in the first direction DR1 and the second direction DR2. Therefore, the shadow areas caused by the mask and deposition defects caused by the deposition process conditions may be reduced. This will be described in detail with reference to FIGS. 7A, 7B, and 8.

FIG. 7A is a schematic cross-sectional view of a process of manufacturing the display panel according to an embodiment of the disclosure. FIG. 7B is a schematic enlarged cross-sectional view of an area bb of FIG. 7A. FIG. 8 is a schematic plan view of a process of manufacturing the display panel according to an embodiment of the disclosure.

The method of manufacturing the display device may include depositing a preliminary pixel definition layer on a process substrate M-SUB on which the first electrodes AE1, AE2, and AE3 are disposed and patterning the preliminary pixel definition layer through which the first, second, and third light emitting openings OP-1, OP-2, and OP-3 are defined to expose at least part of the first electrodes AE1, AE2, and AE3. The method of manufacturing the display device may include forming the light emitting patterns EM1, EM2, and EM3 (e.g., refer to FIG. 6) respectively in the first, second, and third light emitting openings OP-1, OP-2, and OP-3 of the pixel definition layer PDL through the deposition process after the forming of the pixel definition layer PDL. The electron control layer ECL (e.g., refer to FIG. 6) and the second electrode CE (e.g., refer to FIG. 6) may be formed on the light emitting patterns EM1, EM2, and EM3 (e.g., refer to FIG. 6), and thus, the display device DD (e.g., refer to FIG. 1) may be manufactured. The method of manufacturing the display device may include setting the first gap G1 and the second gap G2 in the forming of the pixel definition layer PDL in consideration of a difference in size of the shadow area and a difference in the deviation of the pixel position accuracy (PPA).

The light emitting patterns EM1, EM2, and EM3 (e.g., refer to FIG. 6) may be formed through the deposition process. FIGS. 7A and 7B schematically show the deposition process of forming the light emitting pattern EM1 of the first light emitting element OL1 among the light emitting patterns EM1, EM2, and EM3 as an example. Descriptions about the deposition process of forming the light emitting pattern EM1 of the first light emitting element OL1 (e.g., refer to FIG. 6) may be applied to processes of forming the light emitting patterns EM2 and EM3 (e.g., refer to FIG. 6) of the second and third light emitting elements OL2 and OL3 (e.g., refer to FIG. 6). Thus, detailed description of the same constituent elements is omitted.

Referring to FIGS. 7A and 7B, the process substrate M-SUB may be a process target on which a deposition material is deposited. The process substrate M-SUB may include some components of the display panel DP (e.g., refer to FIG. 6) formed on the base layer BS depending on configurations formed through the deposition process. For example, in the embodiment shown in FIG. 7A, the process substrate M-SUB may include the base layer BS, the circuit layer CL, the first electrodes AE1, AE2, and AE3, the pixel definition layer PDL, the protruding layer HPP, and the hole control layer HCL, and a deposition surface of the process substrate M-SUB may be a surface on which the hole control layer HCL is deposited.

The light emitting pattern EM1 of the first light emitting element OL1 may be formed through the deposition process using the mask MK. The mask MK may include a first surface S1 and a second surface S2. The first surface S1 may face the process substrate M-SUB that is the process target, and the second surface S2 may be opposite to the first surface S1. An opening O-M may be defined through the mask MK. The opening O-M of the mask MK may be formed penetrating through the mask MK from the first surface S1 to the second surface S2.

The opening O-M of the mask MK may define an area in the process substrate M-SUB on which a deposition pattern is formed. The deposition material may pass through the opening O-M of the mask MK and be formed on the deposition surface of the process substrate M-SUB in a pattern (e.g., a predetermined or selectable pattern) corresponding to the opening O-M. The opening O-M of the mask MK to form the light emitting pattern EM1 of the first light emitting element OL1 (e.g., refer to FIG. 6) may overlap an area that is defined as the first light emitting area LA1 in the process substrate M-SUB in a plan view. A size of the opening O-M may be substantially the same as or greater than a size of the first light emitting area LA1 in a plan view. Accordingly, the process margin of the light emitting pattern EM1 may be sufficiently secured, and the light emitting pattern EM1 may be sufficiently deposited in the first light emitting area LA1.

The protruding layer HPP may support the first surface S1 of the mask MK. The protruding layer HPP may protrude from the pixel definition layer PDL toward the mask MK, and the deposition surface corresponding to the first light emitting area LA1 may be spaced apart from the mask MK with a distance (e.g., a predetermined or selectable distance).

The shadow areas SA1 and SA2 may be formed on the deposition surface of the process substrate M-SUB according to a distance between the process substrate M-SUB and the mask MK, a shape and an angle of an inner side surface that defines the opening O-M of the mask MK, a size and a thickness of the mask MK, and an incident angle of the deposition material. The size of the shadow areas SA1 and SA2 may be affected by the distance between the process substrate M-SUB and the mask MK, the shape and the angle of the inner side surface that defines the opening O-M of the mask MK, the size and the thickness of the mask MK, and the incident angle of the deposition material. In the embodiment, the deposition material may not be sufficiently reached in the shadow areas SA1 and SA2 due to an interference of the mask MK, and the shadow areas SA1 and SA2 may be areas in which the deposition pattern (e.g., the light emitting pattern EM1 of the first light emitting element OL1) is insufficiently formed. The shadow areas SA1 and SA2 may correspond to areas in which the light emitting pattern EM1 of the first light emitting element OL1 is deposited with a thickness thinner than a designed thickness in the deposited light emitting pattern EM1. For example, the shadow areas SA1 and SA2 may correspond to areas in which the light emitting pattern EM1 is formed with a thickness thinner (or smaller) than a thickness of the light emitting pattern EM1 at a center of the light emitting opening OP-1 among the areas in which the light emitting pattern EM1 is formed.

Referring to FIGS. 5 to 7B, the size in the first direction DR1 of the shadow area SA1 and the size in the second direction DR2 of the shadow area SA2 may be different from each other depending on the mask MK and an incident angle of the deposition material. For example, a size of the insufficiently formed portion in the light emitting pattern EM1 of the first light emitting element OL1 in the first direction DR1 and a size of the insufficiently formed portion in the light emitting pattern EM1 in the second direction DR2 may be different from each other. In the embodiment, the size of the first gap G1 and the size of the second gap G2 may be adjusted. Thus, the above-described errors (e.g., the difference between the insufficiently formed portions of the light emitting pattern EM1 in the first and second directions DR1 and DR2) may be corrected (or compensated). In case that the size of the shadow areas SA1 and SA2 is large in a direction, the light emitting opening OP-1 may be expanded to be greater than a reference value, and the deposition accuracy may be improved. For example, in case that the size of the shadow areas SA1 and SA2 is large in the direction, the first and second gaps G1 and G2 of the pixel definition layer PDL may be reduced. Thus, the deposition accuracy may be improved.

However, in case that the size of the gaps G1 and G2 of the pixel definition layer PDL is adjusted to improve the deposition accuracy, it is required to consider not only the difference in size of the shadow areas SA1 and SA2, but also locations at which the light emitting patterns EM1, EM2, and EM3 are formed through the deposition process. For example, the difference in size of the shadow areas SA1 and SA2 and the locations at which the light emitting patterns EM1, EM2, and EM3 are formed through the deposition process may be adjusted to control the size of the gaps G1 and G2 of the pixel definition layer PDL. Thus, the deposition accuracy may be improved. For example, in case that the PPA deviation is large, reducing the gap may improve the deposition accuracy even though the size of the shadow area is small in the direction. The PPA deviation may be defined as a deviation between the deposition position of the light emitting pattern that is originally designed and the position of the light emitting pattern that is actually deposited. For example, the PPA deviation may correspond to the difference in position between the center of the light emitting opening in which the light emitting pattern is to be formed and the center of the light emitting pattern that is actually deposited. The deposition accuracy may increase as the difference between the deposition position of the light emitting pattern that is originally designed and the position at which the light emitting pattern is actually deposited decreases. For example, the deposition accuracy may increase as the PPA deviation decreases.

The PPA deviation may correspond to an average value of a dispersion of the PPA deviation of the light emitting patterns EM1, EM2, and EM3 within the display area AA. The PPA deviation of each of the light emitting patterns EM1, EM2, and EM3 may be changed depending on the designed deposition position, the alignment accuracy of the mask MK, and conditions of the deposition process. FIG. 8 schematically shows positions of designed light emitting patterns EM1-R1 and EM1-R2 of the first light emitting element OL1 among the light emitting patterns EM1, EM2, and EM3 and positions at which light emitting patterns EM1-1 and EM1-2 are actually deposited. Hereinafter, for the convenience of explanation, the designed light emitting patterns EM1-R1 and EM1-R2 are respectively referred to as a first design light emitting pattern EM1-R1 and a second design light emitting pattern EM1-R2, and the light emitting patterns EM1-1 and EM1-2 actually deposited are respectively referred to as a first deposition light emitting pattern EM1-1 and a second deposition light emitting pattern EM1-2.

Referring to FIG. 8, the positions of the first and second design light emitting patterns EM1-R1 and EM1-R2 may be positioned in areas from which lights having the same color exit, e.g., the first light emitting areas LA1. A center of the first design light emitting pattern EM1-R1 and a center of the second design light emitting pattern EM1-R2 may be parallel to each other in the second direction DR2.

The first deposition light emitting pattern EM1-1 and the second deposition light emitting pattern EM1-2 may be deposited to respectively overlap the first design light emitting pattern EM1-R1 and the second design light emitting pattern EM1-R2 in a plan view. However, the first deposition light emitting pattern EM1-1 and the second deposition light emitting pattern EM1-2 may be respectively shifted from the first and second design light emitting patterns EM1-R1 and EM1-R2 due to the process errors caused by the alignment of the mask MK and the conditions of the deposition process during the deposition process.

For example, the position of a center of the first deposition light emitting pattern EM1-1 may be different from the position of the center of the first design light emitting pattern EM1-R1. The first deposition light emitting pattern EM1-1 may be shifted from the first design light emitting pattern EM1-R1 by a first distance DX1 in the first direction DR1 and by a second distance DY1 in the second direction DR2.

The position of a center of the second deposition light emitting pattern EM1-2 may be different from the position of the center of the second design light emitting pattern EM1-R2. The second deposition light emitting pattern EM1-2 may be shifted from the second design light emitting pattern EM1-R2 by a third distance DX2 in the first direction DR1 and by a fourth distance DY2 in the second direction DR2.

The first distance DX1 and the third distance DX2 may correspond to PPA deviations of the first and second deposition light emitting patterns EM1-1 and EM1-2 in the first direction DR1, respectively. The second distance DY1 and the fourth distance DY2 may correspond to PPA deviations of the first and second deposition light emitting patterns EM1-1 and EM1-2 in the second direction DR2.

The center of the first deposition light emitting pattern EM1-1 and the center of the second deposition light emitting pattern EM1-2 may have different degrees of shift from a corresponding design light emitting pattern. For example, the third distance DX2 may be greater than the first distance DX1, and the fourth distance DY2 may be greater than the second distance DY1. As described above, the PPA deviations of the deposition light emitting patterns EM1-1 and EM1-2 may be different from each other, and the PPA deviation required to adjust the gaps G1 and G2 of the pixel definition layer PDL may correspond to the average value calculated from the dispersion of the PPA deviation of each of the deposition light emitting patterns EM1-1 and EM1-2. For example, the adjusting amount of the gaps G1 and G2 of the pixel definition layer PDL may be the average value calculated from the dispersion of the PPA deviation of each of the deposition light emitting patterns EM1-1 and EM1-2, and the PPA deviations of the deposition light emitting patterns EM1-1 and EM1-2 may be compensated. The PPA deviation in the first direction DR1 and the PPA deviation in the second direction DR2 may be independently calculated. Descriptions of the PPA deviation are made based on two deposition light emitting patterns EM1-1 and EM1-2 for the convenience of explanation, however, the average value of the PPA deviation may be calculated by taking into account other deposition light emitting patterns.

Descriptions of the sizes of the shadow areas SA1 and SA2 are made based on each light emitting pattern EM1, however, the sizes of the shadow areas SA1 and SA2 may be changed depending on the positions at which the light emitting patterns EM1, EM2, and EM3 are formed. The sizes of the shadow areas SA1 and SA2, which are required to adjust the gaps G1 and G2 of the pixel definition layer PDL, may correspond to the average value calculated from the dispersion of the shadow area of each of the light emitting patterns EM1, EM2, and EM3.

The first gap G1 and the second gap G2 of the pixel definition layer PDL may be designed by taking into account the difference in sizes between the shadow areas SA1 and SA2 in the first direction DR1 and the second direction DR2 and the difference between the PPA deviations in the first direction DR1 and the second direction DR2. The difference between the first gap G1 and the second gap G2 of the pixel definition layer PDL may satisfy the following Equation 1.

$$\vert G 1 - G 2 \vert = \vert 2 [ ( SA 1 - SA 2 ) + ( PPA 1 - PPA 2 ) ] \vert \qquad Equation 1$$

In Equation 1, “G1” denotes the first gap G1 of the pixel definition layer PDL in the first direction DR1, and “G2” denotes the second gap G2 of the pixel definition layer PDL in the second direction DR2. In Equation 1, “SA1” denotes the size in the first direction DR1 of the shadow area SA1, and “SA2” denotes the size in the second direction DR2 of the shadow area SA2. In Equation 1, “PPA1” denotes the PPA deviation in the first direction DR1, and “PPA2” denotes the PPA deviation in the second direction DR2.

Referring to Equation 1, the difference between the first gap G1 and the second gap G2 may be proportional to a sum of the difference between the size in the first direction DR1 of the shadow area SA1 and the size in the second direction DR2 of the shadow area SA2 and the difference between a value of the PPA deviation PPA1 in the first direction DR1 and a value of the PPA deviation PPA2 in the second direction DR2. In the embodiment, for the convenience of explanation, the sum of the difference between the size in the first direction DR1 of the shadow area SA1 and the size in the second direction DR2 of the shadow area SA2 and the difference between the value of the PPA deviation PPA1 in the first direction DR1 and the value of the PPA deviation PPA2 in the second direction DR2 is referred to as a “gap correction value A” as represented by the following Equation 2.

$$gap correction value A = [ ( SA 1 - SA 2 ) + ( PPA 1 - PPA 2 ) ] \qquad Equation 2$$

In case that the gap correction value A is a positive number, the deposition accuracy may be improved by increasing the first gap G1 to be greater than the reference value and decreasing the second gap G2 to be smaller than the reference value. In case that the gap correction value A is the positive number, the first gap G1 may correspond to a value obtained by adding the reference value of a designed gap and the gap correction value A, and the second gap G2 may correspond to a value obtained by subtracting the gap correction value A from the reference value of the designed gap. For example, even though the size in the first direction DR1 of the shadow area SA1 is smaller than the size in the second direction DR2 of the shadow area SA2, the deposition accuracy may be improved by increasing the first gap G1 to be greater than the reference value and decreasing the second gap G2 to be smaller than the reference value in case that the value of the PPA deviation PPA1 in the first direction DR1 is greater than the value of the PPA deviation PPA2 in the second direction DR2 by more than the difference in size between the shadow areas SA1 and SA2.

In case that the gap correction value A is a negative number, the deposition accuracy may be improved by decreasing the first gap G1 to be smaller than the reference value and increasing the second gap G2 to be greater than the reference value. In case that the gap correction value A is the negative number, the first gap G1 may correspond to the value obtained by subtracting the gap correction value A from the reference value of the designed gap, and the second gap G2 may correspond to the value obtained by adding the reference value of the designed gap and the gap correction value A. For example, even though the size in the second direction DR2 of the shadow area SA2 is smaller than the size in the first direction DR1 of the shadow area SA1, the deposition accuracy may be improved by increasing the second gap G2 to be greater than the reference value and decreasing the first gap G1 to be smaller than the reference value in case that the value of the PPA deviation PPA2 in the second direction DR2 is greater than the value of the PPA deviation PPA1 in the first direction DR1 by more than the difference in size between the shadow areas SA1 and SA2.

According to the display device DD, the difference between the gaps G1 and G2 of the pixel definition layer PDL disposed between the light emitting areas LA1, LA2, and LA3 may be proportional to the size difference between the shadow areas SA1 and SA2 in the direction and the difference in the PPA deviation between the light emitting patterns EM1, EM2, and EM3 in the direction. Accordingly, the deposition defects caused by the conditions of the deposition process and the shadow area may be reduced, and the reliability of the display device DD may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a circuit layer disposed on a base layer;
a pixel definition layer disposed on the circuit layer and provided with a first light emitting opening, a second light emitting opening, and a third light emitting opening;
a first light emitting element disposed on the circuit layer and comprising a light emitting pattern disposed in the first light emitting opening;
a second light emitting element disposed on the circuit layer and comprising a light emitting pattern disposed in the second light emitting opening; and
a third light emitting element disposed on the circuit layer and comprising a light emitting pattern disposed in the third light emitting opening, wherein
the pixel definition layer comprises:
a first gap corresponding to a distance between the first light emitting opening and the third light emitting opening; and
a second gap corresponding to a distance between the first light emitting opening and the second light emitting opening, and
a difference between the first gap and the second gap is determined according to a difference in size of a shadow area of at least one of the light emitting patterns and a difference in a deviation of a pixel position accuracy (PPA) of the at least one of the light emitting patterns.

2. The display device of claim 1, wherein the first, second, and third light emitting elements emit first, second, and third color lights different from each other.

3. The display device of claim 2, wherein the third color light has a wavelength range smaller than a wavelength range of the first color light and a wavelength range of the second color light.

4. The display device of claim 3, wherein the first color light, the second color light, and the third color light are respectively red, green, and blue color lights.

5. The display device of claim 2, wherein
the first light emitting opening and the second light emitting opening are spaced apart from the third light emitting opening in a first direction, and
the first light emitting opening is spaced apart from the second light emitting opening in a second direction intersecting the first direction.

6. The display device of claim 5, wherein the third light emitting opening overlaps the first light emitting opening and the second light emitting opening in the first direction.

7. The display device of claim 6, wherein a length in the second direction of the third light emitting opening is greater than a length in the second direction of the first light emitting opening.

8. The display device of claim 5, wherein
the shadow area corresponds to a part of areas in which the at least one of the light emitting patterns is disposed, and
the at least one of the light emitting patterns in the shadow area has a thickness smaller than a thickness of the at least one of the light emitting patterns at a center of at least one of the first, second, and third light emitting openings corresponding to the at least one of the light emitting patterns.

9. The display device of claim 8, wherein the deviation of the PPA corresponds to a difference in position between the center of the at least one of the first, second, and third light emitting openings corresponding to the at least one of the light emitting patterns and a center of the at least one of the light emitting patterns.

10. The display device of claim 9, wherein the first gap (G1) and the second gap (G2) satisfy the following Equation 1:

|G1−G2|=|2[(SA1−SA2)+(PPA1−PPA2)]|, wherein
SA1 denotes a size in the first direction of the shadow area,
SA2 denotes a size in the second direction of the shadow area,
PPA1 denotes a difference in position between a center of the at least one of the first, second, and third light emitting openings and a center of the at least one of the light emitting patterns in the first direction, and
PPA2 denotes a difference in position between a center of the at least one of the first, second, and third light emitting openings and a center of the at least one of the light emitting patterns in the second direction.

11. The display device of claim 10, wherein the first gap is greater than the second gap in case that a sum of a difference between the SA1 and the SA2 and a difference between the PPA1 and the PPA2 is a positive number.

12. The display device of claim 10, wherein the first gap is smaller than the second gap in case that a sum of a difference between the SA1 and the SA2 and a difference between the PPA1 and the PPA2 is a negative number.

13. A display device comprising:
a circuit layer disposed on a base layer;
a pixel definition layer disposed on the circuit layer and provided with a first light emitting opening, a second light emitting opening, and a third light emitting opening;
a first light emitting element disposed in the first light emitting opening and comprising a light emitting pattern;
a second light emitting element disposed in the second light emitting opening and comprising a light emitting pattern; and
a third light emitting element disposed in the third light emitting opening and comprising a light emitting pattern, wherein
the first light emitting opening and the third light emitting opening are spaced apart from each other with a first gap in a first direction,
the first light emitting opening and the second light emitting opening are spaced apart from each other with a second gap in a second direction intersecting the first direction, and
a difference between the first gap and the second gap is determined according to a difference in size of a shadow area of at least one of the light emitting patterns and a difference in a deviation of a pixel position accuracy (PPA) of the at least one of the light emitting patterns.

14. A method of manufacturing a display device, comprising:
providing a process substrate comprising first electrodes;
forming a pixel definition layer which is provided with a first light emitting opening, a second light emitting opening, and a third light emitting opening to respectively expose portions of the first electrodes, on the process substrate;
forming a light emitting pattern overlapping each of the first, second, and third light emitting openings in a plan view; and
forming a second electrode on the light emitting pattern, wherein
the forming of the pixel definition layer comprises:
determining a first gap corresponding to a distance between the first light emitting opening and the third light emitting opening; and
determining a second gap corresponding to a distance between the first light emitting opening and the second light emitting opening, and
a difference between the first gap and the second gap is determined according to a difference in size of a shadow area of at least one of the light emitting patterns and a difference in a deviation of a pixel position accuracy (PPA) of the at least one of the light emitting patterns.

15. The method of claim 14, wherein
the first light emitting opening and the second light emitting opening are spaced apart from the third light emitting opening in a first direction, and
the first light emitting opening is spaced apart from the second light emitting opening in a second direction intersecting the first direction.

16. The method of claim 15, wherein
the shadow area corresponds to a part of areas in which the at least one of the light emitting patterns is disposed, and
the at least one of the light emitting patterns in the shadow area has a thickness smaller than a thickness of the at least one of the light emitting patterns at a center of at least one of the first, second, and third light emitting openings corresponding to the at least one of the light emitting patterns.

17. The method of claim 16, wherein the deviation of the PPA corresponds to a difference in position between a center of a designed light emitting pattern and a center of a deposited light emitting pattern.

18. The method of claim 17, wherein the first gap (G1) and the second gap (G2) satisfy the following Equation 1:

|G1−G2|=|2[(SA1−SA2)+(PPA1−PPA2)]|, wherein
SA1 denotes a size in the first direction of the shadow area,
SA2 denotes a size in the second direction of the shadow area,
PPA1 denotes a difference in position between a center of the at least one of the first, second, and third light emitting openings and a center of the at least one of the light emitting patterns in the first direction, and
PPA2 denotes a difference in position between a center of the at least one of the first, second, and third light emitting openings and a center of the at least one of the light emitting patterns in the second direction.

19. The method of claim 18, wherein the first gap is greater than the second gap in case that a sum of a difference between the SA1 and the SA2 and a difference between the PPA1 and the PPA2 is a positive number.

20. The method of claim 18, wherein the first gap is smaller than the second gap in case that a sum of a difference between the SA1 and the SA2 and a difference between the PPA1 and the PPA2 is a negative number.
